(19) United States
(12) Patent Application Publication
(10) Pub. No.: US 2016/0064070 A1
(43) Pub. Date: Mar. 3, 2016

(54) LOW POWER SRAM

(71) Applicant: TEXAS INSTRUMENTS INCORPORATED, Dallas, TX (US)

(72) Inventors: Vinod MENEZES, Bangalore (IN); Premkumar SEETHARAMAN, Bangalore (IN)

(21) Appl. No.: 14/843,080

(22) Filed: Sep. 2, 2015

(30) Foreign Application Priority Data
Sep. 2, 2014 (IN) 4278/CHE/2014

(51) Int. Cl. G11C 11/419

(52) U.S. Cl. CPC G11C 11/419

(57) ABSTRACT

A static random access memory (SRAM) that includes an array of storage cells arranged as rows and columns and a read controller to manage reading from the storage cells. The array of storage cells includes word lines that correspond to the rows and bit lines that correspond to the columns. The read controller is configured to identify consecutive reads from storage cells accessed via a same one of the word lines and precharge the bit lines no more than once during the consecutive reads.

### CROSS-REFERENCE TO RELATED APPLICATIONS

The present application claims priority to India Provisional Patent Application No. 4278/CHE/2014, filed Sep. 2, 2014, which is hereby incorporated herein by reference in its entirety.

### BACKGROUND

Static random access memory (SRAM) is memory that utilizes latching to store each bit. Because SRAM is static, there is no need to periodically refresh the memory, and is, therefore, typically faster, less dense, and more expensive, than dynamic random-access memory (DRAM). Due to SRAM's speed, SRAM is typically used in computer applications that require a fast memory such as cache memory for the central processing unit (CPU), external burst mode SRAM caches, hard disk buffers, router buffers, CPU register files, etc. While SRAM is fast, it also consumes a significant portion of system's level dynamic power. In some cases SRAM may consume as much as 90% of the system level dynamic power.

### SUMMARY

The problems noted above are solved in large part by systems and methods for reducing power consumption in static random access memory (SRAM). In some embodiments, a SRAM includes an array of storage cells arranged as rows and columns and a read controller to manage reading from the storage cells. The array of storage cells includes word lines that correspond to the rows and bit lines that correspond to the columns. The read controller is configured to identify consecutive reads from storage cells accessed via a same one of the word lines and precharge the bit lines no more than once during the consecutive reads.

Another illustrative embodiment is a method for reducing power consumption in SRAM. The method may comprise precharging a plurality of bit lines of an array of storage cells arranged as rows and columns. The plurality of bit lines corresponds to the columns. The method may also comprise activating a first word line of the array of storage cells. The first word line corresponds to a first of the rows. The method may also comprise identifying consecutive reads from the storage cells accessed via the first word line. The method also may comprise reading, as part of the consecutive reads, a first storage cell and a second storage cell without precharging the bit lines between the reading of the first and second storage cells.

Yet another illustrative embodiment is an integrated circuit that includes a processor and SRAM coupled to the processor. The SRAM comprises an array of storage cells arranged as rows and columns and a read controller to manage reading from the storage cells. The SRAM includes word lines that correspond to the rows and bit lines that correspond to the columns. The read controller comprises precharge circuitry that is configured to identify consecutive reads to storage cells accessed via a same one of the word lines and precharge the bit lines on fewer than all the consecutive reads.

### BRIEF DESCRIPTION OF THE DRAWINGS

For a detailed description of various examples, reference will now be made to the accompanying drawings in which:

FIG. 1 shows a block diagram of an integrated circuit in accordance with various embodiments;

FIG. 2 shows a block diagram of a static random access memory (SRAM) in accordance with various embodiments;

FIG. 3 shows a block diagram of storage cell array in accordance with various embodiments;

FIG. 4 shows a flow diagram of a method for reducing power consumption in a SRAM in accordance with various embodiments; and

FIG. 5 shows a flow diagram of a method for reading storage cells in a SRAM in accordance with various embodiments.

### NOTATION AND NOMENCLATURE

Certain terms are used throughout the following description and claims to refer to particular system components. As one skilled in the art will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . . ” Also, the term “couple” or “couples” is intended to mean either an indirect or direct connection. Thus, if a first device couples to a second device, that connection may be through a direct connection, or through an indirect connection via other devices and connections. The recitation “based on” is intended to mean “based at least in part on.” Therefore, if X is based on Y, X may be based on Y and any number of other factors.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

Static random access memory (SRAM) is memory that utilizes latching to store each bit. Because SRAM is static, there is no need to periodically refresh the memory, and is, therefore, typically faster, less dense, and more expensive, than dynamic random-access memory (DRAM). Due to SRAM's speed, SRAM is typically used in computer applications that require a fast memory such as cache memory for the central processing unit (CPU), external burst mode SRAM caches, hard disk buffers, router buffers, CPU register files, etc. Therefore, SRAM is a fundamental building block of many systems. While SRAM is fast, it also consumes a significant portion of system's level dynamic power. In some cases SRAM may consume as much as 90% of the system level dynamic power. Therefore, it is desirable to reduce the power consumption of SRAM.

A conventional SRAM design always precharges each differential pair of bit lines in the columns of a memory storage array on every read access. Therefore, whenever a storage cell in the storage cell array is to be read, a precharge of the bit lines is initiated. Once the bit lines are precharged in the conventional SRAM, the word line corresponding to the row in which the storage cell to be read is activated. This creates a differential voltage in the columns containing the storage cell being read allowing a sense amplifier to read the contents of the storage cell. If another storage cell is to be read, the process repeats beginning with a precharge of the bit lines. This repeated precharging of the bit lines creates a high level of power consumption.

Instead of precharging on every read, each precharge may be done selectively. The bit lines may not be precharged when a linear burst read is performed such that the same row address (i.e., same word line is activated) is utilized for a consecutive read. For example, after a first read of a storage cell, a precharge may not be performed if the next storage cell to be read is on the same word line, but is in a different column of the storage array. This reduces power consumption by as much as 50% in the SRAM.

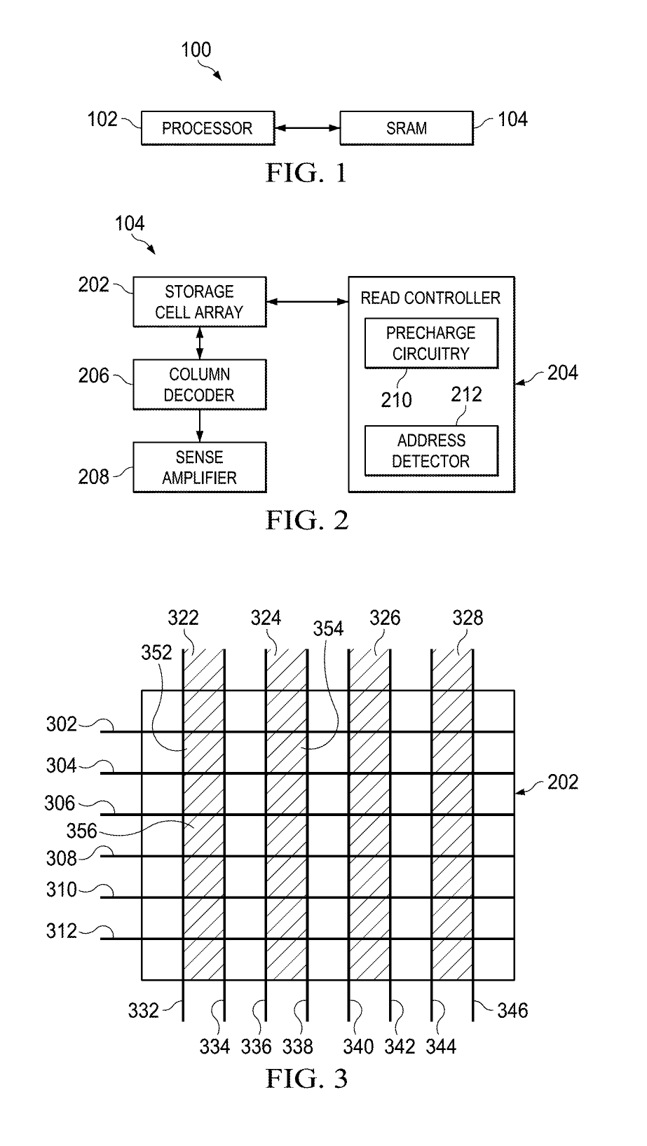

FIG. 1 shows a block diagram of an integrated circuit 100 in accordance with various embodiments. Integrated circuit 100 may include processor 102 and SRAM 104, which may, in some embodiments, be coupled to processor 102. Integrated circuit 100 may also include various additional components, such as transceivers, clock generators, ports, etc.; however, these components have been omitted to promote clarity. Processor 102 may be a control processor, a signal processor, a central processor, or any other type of processor. Processor 102 may be, for example, a general-purpose microprocessor, a digital signal processor, a microcontroller, or other suitable device configured to execute instructions for performing operations. Processor architectures generally include execution units (e.g., fixed point, floating point, integer, etc.), instruction decoding, peripherals (e.g., interrupt controllers, timers, direct memory access controllers, etc.), input/output systems (e.g., serial ports, parallel ports, etc.) and various other components and sub-systems.

SRAM 104 is static random access memory which may provide storage of data and/or instructions that are capable of being processed by processor 102. SRAM 104 is designed such that it exhibits data remanence and utilizes latching circuitry to store each bit of data. SRAM 104 is coupled to processor 102 such that processor 102 may read from and/or write data and/or instructions to SRAM 104 for storage. In some embodiments, SRAM 104 is a part of processor 102 while in alternative embodiments, SRAM 104 is distinct from processor 102. Furthermore, multiple SRAMs 104 may be included in integrated circuit 100.

FIG. 2 shows a block diagram of a SRAM 104 in accordance with various embodiments. SRAM 104 may include storage cell array 202, read controller 204, column decoder 206, and sense amplifier 208. Storage cell array 202 may be arranged as rows and columns of storage cells, sometimes referred to as bit cells, each storage cell storing one bit of data.

FIG. 3 shows a block diagram of storage cell array 202 in accordance with various embodiments. Storage cell array 202 may include word lines 302-312 which correspond to the rows of storage cell array 202 and columns 322-328. Each of columns 322-328 may be comprised of a differential pair of bit lines. For example, column 322 may be comprised of bit lines 332-334; column 324 may be comprised of bit lines 336-338; column 326 may be comprised of bit lines 340-342; and column 328 may be comprised of bit lines 344-346. At the intersection of each of the word lines 302-312 and the columns 322-328, are the storage cells, such as storage cells 352, 354 and 356, that make up storage cell array 202.

Each of the storage cells in storage array 202, such as storage cells 352, 354, and 356 may be arranged to store a single bit of data. In some embodiments, each of the storage cells comprises a six-transistor (“6T”) SRAM cell that is formed with a pair of cross-coupled inverters. Each inverter includes a p-channel transistor and an n-channel transistor. The source of a first pass gate transistor is connected to the gate nodes of the first inverter and the drain nodes of the second inverter. Similarly, the source of a second pass gate transistor, is connected to the gate nodes of the second inverter and the drain nodes of the first inverter. The gates of the pass gate transistors are connected to a common word line, such as word line 302 for storage cells 352 and 354 and word line 308 for storage cell 356, while the drains of the pass gate transistors are connected to a differential pair of bit lines, such as bit lines 332 and 334 for storage cells 352 and 356 and bit lines 336 and 338 for storage cell 354. In alternative embodiments, the storage cells of storage array 202 may be any type of SRAM bit cell, such as a four-transistor (“4T”) SRAM cell, an eight-transistor (“8T”) SRAM cell, a ten-transistor (“10T”) SRAM cell, or any other SRAM storage cell.

Returning to FIG. 2, read controller 204 is coupled to storage cell array 202 and is configured to manage the reading of the storage cells contained in storage cell array 202. Read controller 204 may comprise precharge circuitry 210 and address detector 212. Read controller may be any type of memory controller that manages the flow of data going from and to storage cell array 202. At the beginning of a read cycle, precharge circuity 210 is configured to cause each of the differential pairs of bit lines (both positive and negative signals) to precharge to a common voltage. In order to read any of the storage cells, the word line corresponding to the storage cell to be read is activated. For example, if storage cell 352 is to be read, then word line 302 is activated. In some embodiments, a row controller (not shown) may cause the word line to activate. Once the word line is activated, each of the pass gate transistors from each of the storage cells on the activated word line is enabled. For example, if word line 302 is activated, then pass gate transistors in storage cells 352 and 354, as well as the pass gate transistors for any other storage cell connected to word line 302 are enabled. This causes the bit line voltage for one of the two differential pairs of bit lines connected to each of the storage cells to drop based on whether the storage cell connected to the differential pair stores a 0 or a 1. For example, once word line 302 is activated, the voltage along bit line 332 or 334 will drop based on whether storage cell 352 stores a 0 or a 1. Similarly, the voltage along bit line 336 or 338 will drop based on whether storage cell 354 contains a 0 or a 1.

Column decoder 206 determines which of the columns 322-328 from FIG. 3 contains the storage cell that is to be read. More specifically, column decoder 206 is configured to receive an output signal from each of the columns 322-328 and select the output signal form the column corresponding to the storage cell being read. Each of the output signals corresponds to the differential voltage carried in the differential pair of bit lines. For example, if storage cell 352 is to be read, column decoder 206 selects column 322 and its differential pair of bit lines 332-334. Sense amplifier 208 then may sense which of the selected differential pair of bit lines has the higher voltage through amplification, thus determining whether the storage cell stores a 0 or a 1. In other words, the sense amplifier 208 is configured to determine the state of the selected column by sensing the column voltage differential. Continuing the previous example, once column decoder 206 selects column 322, the sense amplifier will sense, or determine, which of bit lines 332 and 334 has a higher voltage. Once this is determined, the state of storage cell 352 is able to be determined.

Read controller 204 then may identify consecutive reads from storage cells accessed via the same word line. For example, if a read from storage cell 352 is immediately followed by a read from storage cell 354, which is on the same word line, word line 302, as storage cell 352, read controller 204 makes this identification. Unlike the conventional SRAM, if an identification is made that consecutive reads from storage cells accessed via the same word line is made by read controller 204, the bit lines 332-346 are not precharged between these two reads. Because activation of a specified word line creates a differential for each of the storage cells on the word line that represents the state of the bit in each of the storage cells, no precharge is necessary for reading other storage cells on the same word line. Therefore, the bit lines 332-346 may only be precharged once in conjunction with the consecutive reads—prior to, or at the start of the consecutive reads. By reducing the number of precharges (i.e., by not precharging the differential pair of bit lines after every read), power consumed by the SRAM 104 is reduced.

At the end of the read cycle (once the consecutive reads ends), precharge circuitry 210 is configured to once again cause each of the differential pairs of bit lines to precharge to a common voltage. More specifically, address detector 212 is configured to determine (i.e., detect) any row address change request in SRAM 104. In other words, address detector 212 is configured to determine if and when a request is made of SRAM 104 to read a storage cell in storage array 202 that is not on the word line currently being read. Once address detector 212 detects the row address change request, read controller 204, utilizing precharge circuitry 210, causes each of the differential pairs of bit lines 332-346 to precharge to enable reading storage cells on the different word line. For example, if storage cell 352 is being read, word line 302 is activated. However, if address detector 212 detects a row address change request, such that storage cell 356 is to be read, then word line 306 needs to be activated. Because word line 306 is a different word line (on a different row) than word line 302, precharge circuitry 210 causes the differential pairs of bit lines 332-346 to precharge. Thus, read controller 204 may store an indication of which word line is last asserted (in this example word line 302). Based on the word line currently being asserted or which will be asserted (word line 306 in this example) being different than the word line last asserted (word line 302), precharge circuitry 210 causes a precharge of the bit lines 332-346.

After a period of time elapses from the activation of a word line, the differential pair of bit lines 332-346 may begin to discharge to the point where reading the storage cell becomes difficult if the bit lines are not precharged. For example, prior to the read cycle, bit lines 332-346 may be precharged and a word line activated, such as word line 302. After a period of time, if the bit lines are not precharged again, the bit lines may discharge such that the contents of the storage cells are not readable. Therefore, read controller 204 may determine the amount of time after an activation of the word line that has elapsed, and if the elapsed time is greater than a threshold value, cause the bit lines 332-346 to precharge. In other words, based on a determination that a time period above a threshold value has elapsed since an immediately previous access to the storage cells has occurred, read controller 204 causes the bit lines to precharge. This threshold value may be based on the amount of time it takes to discharge the bit lines 332-346. Thus, SRAM 104 has a built in safe guard to ensure that the storage cells in storage array 202 are always readable. By reducing the number of precharges of the bit lines 332-346 in storage array 202 to only before and after consecutive reads via the same word line or after a predetermined threshold value of elapsed time has passed since an access, SRAM 104 has much lower power requirements than a conventional SRAM.

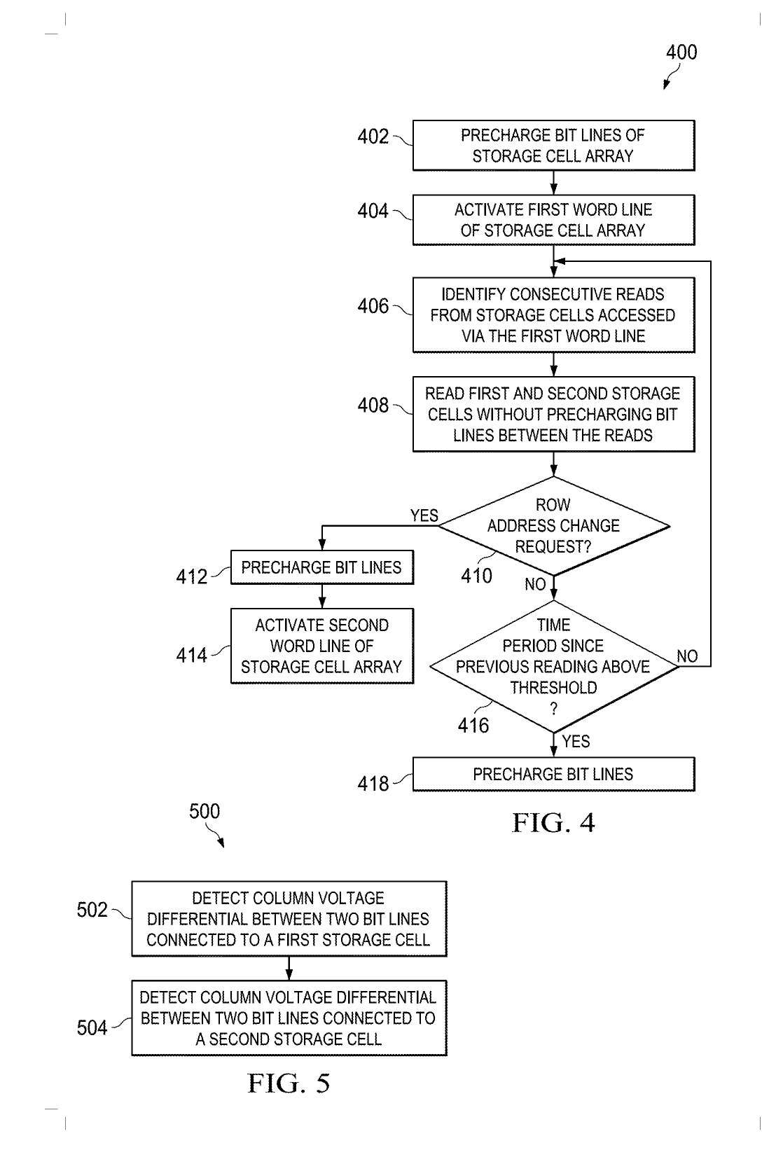

FIG. 4 shows a flow diagram of methods 400 for reducing power consumption in a SRAM, such as SRAM 104, in accordance with various embodiments. FIG. 5 shows a flow diagram of a method 500 for reading storage cells in a SRAM, such as SRAM 104, in accordance with various embodiments. Though depicted sequentially as a matter of convenience, at least some of the actions shown in methods 400 and 500 can be performed in a different order and/or performed in parallel. Additionally, some embodiments may perform only some of the actions shown or may perform additional actions. In some embodiments, at least some of the operations of the methods 400 and 500, as well as other operations described herein, can be performed by SRAM 104 and/or read controller 204 implemented by a processor executing instructions stored in a non-transitory computer readable storage medium or a state machine.

The method 400 begins in block 402 with precharging bit lines of a storage cell array, such as bit lines 332-346 of storage cell array 202. In block 404, the method 400 continues with activating a first word line of the storage cell array. For example, word line 302 may be activated so as to read the contents of a storage cell on word line 302, such as storage cell 352. By activating the word line, a differential is created between each of a plurality of differential pairs of bit lines that make up a column in the storage cell array. A column decoder, such as column decoder 206, then may select an output signal from the column corresponding to the storage cell being read, and a sense amplifier, such as sense amplifier 208, may sense the state of the storage cell being read.

The method 400 continues in block 406 with identifying, in some embodiments by read controller 204, consecutive reads from storage cells accessed via the first word line. For example, read controller 204 may be configured to determine whether storage cell 354, which is accessed via word line 302, is being read consecutively after storage cell 352, which is also accessed via word line 302. In block 408, the method 400 continues with reading a first and second storage cell without precharging bit lines between the reads. Continuing the previous example, once the differential of bit lines 332 and 334 are sensed by sense amplifier 208 to read the contents of storage cell 352, the differential of bit lines 336 and 338 are sensed by sense amplifier 208 to read the contents of storage cell 354 without precharging the bit lines 332-346 between the reads.

The method 400 continues in block 410 with a determination of whether a row address change request has been made. This determination may be made by address detector 212 within read controller 204. Based on a determination in block 410 that a row address change request has been made, in block 412, the method 400 continues with precharging the bit lines, such as bit lines 332-346. In block 414, the method 400 continues with activating a second word line of the storage cell array.

However, if, in block 410, a determination is made that a row address change request has not been made, then the method 400 continues in block 416 with determining whether the time period since an immediate previous reading is above a threshold value. This determination may be made by read controller 204. If in block 416 a determination is made that the time period since the immediate previous reading is not above the threshold value, then the method 400 continues in block 406 with identifying consecutive reads from the storage cells accessed via the same word line as the immediate previous read. However, if in block 416 a determination is made that the time period since the immediate previous reading is above the threshold value, then the method 400 continues in block 418 with precharging the bit lines, such as bit lines 332-346.

The method 500 is a method for reading storage cells in a SRAM, such as SRAM 104. The method 500 begins in block 502 with detecting a column voltage differential between two bit lines connected to a first storage cell. For example, if reading storage cell 352, the column voltage differential of column 322 carried by differential pair of bit lines 332 and 334 is detected by sense amplifier 208. In block 504, the method 500 continues with detecting a column voltage differential between two bit lines connected to a second storage cell. For example, if reading storage cell 354 as the second storage cell, the column voltage differential of column 324 carried by differential pair of bit lines 336 and 338 is detected by sense amplifier 208. In this way, storage cells 352 and 354 may be read without precharging the bit lines 332-346 between the reads.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A static random access memory (SRAM), comprising:
an array of storage cells arranged as rows and columns, and comprising word lines that correspond to the rows and bit lines that correspond to the columns; and
a read controller to manage reading from the storage cells, the read controller configured to:
identify consecutive reads from storage cells accessed via a same one of the word lines; and
precharge the bit lines no more than once during the consecutive reads.

2. The SRAM of claim 1 wherein the read controller is further configured to perform only a single precharge of the bit lines in conjunction with the consecutive reads.

3. The SRAM of claim 1 wherein the read controller is further configured to detect any row address change request in the SRAM and precharge the bit lines in response to detecting the row address change request.

4. The SRAM of claim 1 wherein the read controller is further configured to, based on a determination that a time period above a threshold value has elapsed since an immediately previous access to the storage cells, precharge the bit lines.

5. The SRAM of claim 1, wherein the read controller is further configured to:
store an indication of which one of the word lines was last asserted; and
perform a precharge of the bit lines based on one of the word lines currently asserted being different from the one of the word lines that was last asserted.

6. The SRAM of claim 1, further comprising:
a column decoder configured to receive an output signal from each of the columns and select the output signal from the column corresponding to the storage cell being read, each of the output signals corresponding to a differential voltage in each of the columns; and
a sense amplifier configured to determine a state of the selected column by sensing the column voltage differential for the selected column.

7. The SRAM of claim 1, wherein the read controller is further configured to perform a precharge of the bit lines at a start of the consecutive reads.

8. The SRAM of claim 1 wherein the read controller is further configured to perform a precharge of the bit lines at an end of the consecutive reads.

9. A method for reducing power consumption in static random access memory (SRAM), comprising:
precharging a plurality of bit lines of an array of storage cells arranged as rows and columns, the plurality of bit lines corresponding to the columns;
activating a first word line of the array of storage cells, the first word line corresponding to a first of the rows;
identifying consecutive reads from the storage cells accessed via the first word line; and
reading, as part of the consecutive reads, a first storage cell and a second storage cell without precharging the bit lines between the reading of the first and second storage cells.

10. The method of claim 9, wherein the reading the first and second storage cells comprises:
detecting a column voltage differential between two bit lines connected to the first storage cell; and
detecting a column voltage differential between two bit lines connected to the second storage cell.

11. The method of claim 9, further comprising:
detecting a row address change request in the SRAM; and
precharging the bit lines in response to detecting the row address change request.

12. The method of claim 9, further comprising, based on a determination that a time period above a threshold value has elapsed since an immediately previous reading of the storage cells, precharging the bit lines.

13. The method of claim 9, further comprising:
activating a second word line of the array of storage cells, the second word line corresponding to a second of the rows; and
precharging the bit lines based on activating the second word line.

14. The method of claim 9, further comprising:
precharging the bit lines at a start of the consecutive reads; and
precharging the bit lines at an end of the consecutive reads.

15. An integrated circuit, comprising:
a processor; and
a static random access memory (SRAM) coupled to the processor, the SRAM comprising:
an array of storage cells arranged as rows and columns, the SRAM comprising word lines that correspond to the rows and bit lines that correspond to the columns; and
a read controller to manage reading from the storage cells, the read controller comprising precharge circuitry configured to:
identify consecutive reads to storage cells accessed via a same one of the word lines; and
precharge the bit lines on fewer than all the consecutive reads.

16. The integrated circuit of claim 15, wherein the precharge circuitry is further configured to precharge the bit lines only once in conjunction with the consecutive reads.

17. The integrated circuit of claim of claim 15 wherein the read controller further comprises an address detector configured to detect any row address change request in the SRAM.

18. The integrated circuit of claim 17, wherein the precharge circuitry is further configured to precharge the bit lines in response to a row address change request.

19. The integrated circuit of claim 15, wherein the precharge circuitry is further configured to, based on a determination that a time period above a threshold value has elapsed since an immediately previous access to the storage cells, precharge the bit lines.

20. The integrated circuit of claim 15, wherein the precharge circuitry is configured to perform a precharge of the bit lines at a start of the consecutive reads and at the end of the consecutive reads.
